(19) United States
(12) Patent Application Publication
(10) Pub. No.: US 2013/0162118 A1
(43) Pub. Date: Jun. 27, 2013

(54) ELECTRONIC DEVICE ENCLOSURE ASSEMBLY

(71) Applicant: CHEN-LU FAN, Tu-Cheng (TW)

(72) Inventor: CHEN-LU FAN, Tu-Cheng (TW)

(21) Appl. No.: 13/667,189

(22) Filed: Nov. 2, 2012

(30) Foreign Application Priority Data
Dec. 27, 2011 (TW) 100149029

(51) Int. Cl. H05K 5/02; A47B 87/00

(52) U.S. Cl. 312/111; 312/223.1

(57) ABSTRACT

An electronic device enclosure assembly includes a first electronic device enclosure, a second electronic device enclosure, and a connecting assembly. The connecting assembly includes a first installation member, a second installation member, a connecting member, a rotating member, and a mounting member secured to the rotating member. The first installation member is secured to the first electronic device enclosure. The second installation member is secured to the second electronic device enclosure. The connecting member is rotatably mounted to the first installation member and the rotating member. The rotating member is rotatably mounted to the second installation member. The second installation member defines a locking hole. The mounting member is capable of engaging in the locking hole to prevent the rotating member from rotating relative to the second installation. The connecting member secures the first installation member to the second installation member.

### BACKGROUND

1. Technical Field

The present disclosure relates to electronic device enclosure assemblies, and particularly to an electronic device enclosure assembly with a connecting assembly.

2. Description of Related Art

A server cabinet may comprise a plurality of electronic systems, such as a power system, a control system, an exchange system, and so on. When a plurality of server cabinets is used or transported, and if no connecting assemblies are provided, the plurality of server cabinets may be disorderly placed and may occupy a lot of space, and the plurality of server cabinets may be easily damaged during usage or transportation.

Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of an electronic device enclosure assembly.

FIG. 2 is an exploded, isometric view of a connecting assembly of the electronic device enclosure assembly of FIG. 1.

FIG. 3 is similar to FIG. 2, but viewed from a different aspect.

FIG. 4 is an assembled, isometric view of the connecting assembly of FIG. 2, and shows a connecting member and a rotating member in a locked position.

FIG. 5 is similar to FIG. 4, but shows the connecting member and the rotating member in an unlocked position.

FIG. 6 is an assembled, isometric view of the electronic device enclosure assembly of FIG. 1, and shows the connecting member and the rotating member in the locked position.

FIG. 7 is similar to FIG. 6, but shows the connecting member and the rotating member in the unlocked position.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

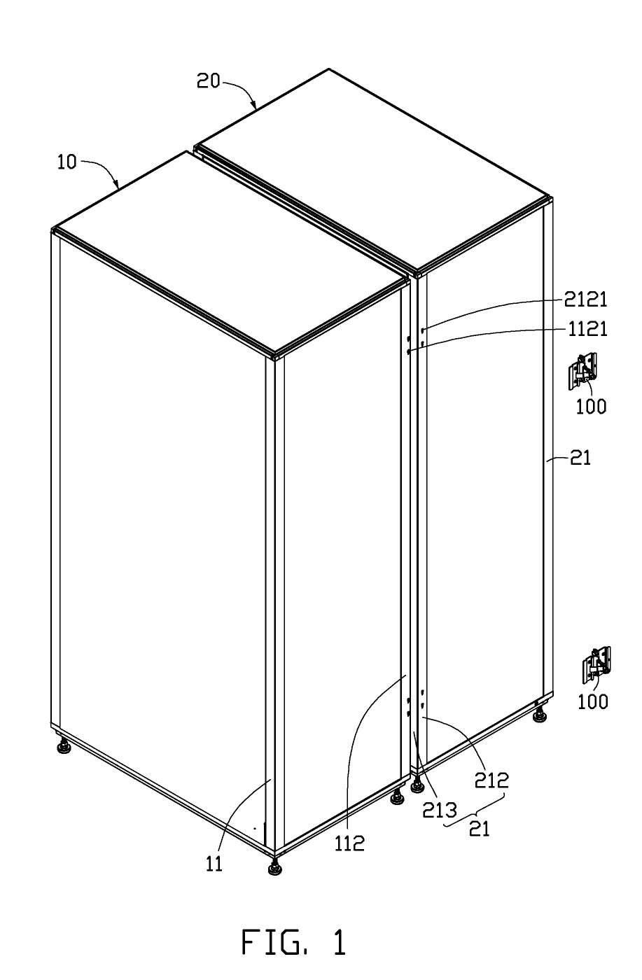

Referring to FIG. 1, an electronic device enclosure assembly in accordance with an embodiment is shown. The electronic device enclosure assembly comprises a first electronic device enclosure 10, a second electronic device enclosure 20, and two connecting assemblies 100.

The first electronic device enclosure assembly 10 comprises a plurality of first supports 11. Each first support 11 comprises a first front plate 112. The first front plate 112 defines a plurality of first installation slots 1121.

The second electronic device enclosure assembly 20 comprises a plurality of second supports 21. Each second support 21 comprises a second front plate 212 and a mounting plate 213. The second front plate 212 defines a plurality of second installation slots 2121. The mounting plate 213 is substantially perpendicular to the second front plate 212 and defines two mounting holes (not shown).

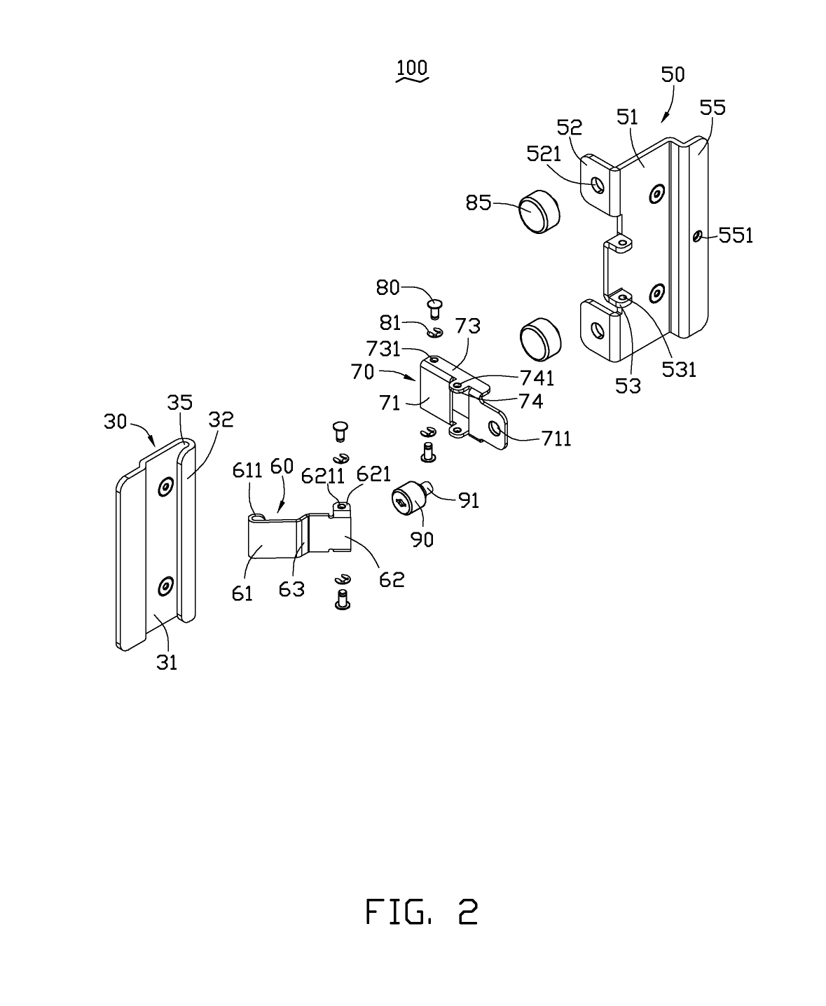

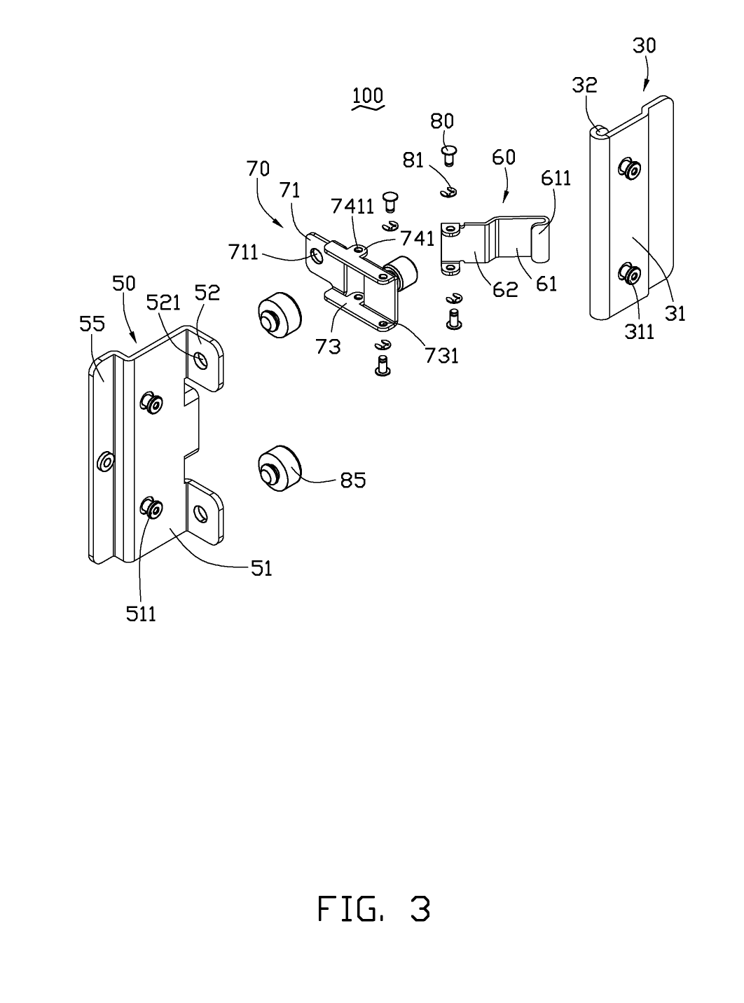

Referring to FIG. 2 and FIG. 3, each connecting assembly 100 comprises a first installation member 30, a second installation member 50, a connecting member 60, and a rotating member 70.

The first installation member 30 comprises a first installation piece 31 and a flange 32 bent from a side edge of the first installation piece 31. A latching slot 35 is defined between the first installation piece 31 and the flange 32. Two first installation posts 311 protrude from the first installation piece 31 away from the flange 32.

The second installation member 50 comprises a second installation piece 51, two mounting pieces 52, two first pivoting pieces 53, and a locking piece 55. The two mounting pieces 52 and the two first pivoting pieces 53 extend from a first edge of the second installation piece 51. The locking piece 55 extends from a second edge of the second installation piece 51 and defines a locking hole 551. The first edge of the second installation piece 51 is substantially perpendicular to the second edge of the second installation piece 51. In one embodiment, the two mounting pieces 52 and the two first pivoting pieces 53 are substantially perpendicular to the second installation piece 51, and the two mounting pieces 52 are substantially perpendicular to the two pivoting pieces 53. Two second installation posts 511 protrude from the second installation piece 51 away from the two pivoting pieces 53. Each mounting piece 52 defines an installation hole 521. Each first pivoting piece 53 defines a first pivoting hole 531.

The connecting member 60 comprises a first connecting piece 61, a second connecting piece 62, and a third connecting piece 63. The first connecting piece 61 and the second connecting piece 62 extend from two opposite edges of the third connecting piece 63. In one embodiment, the first connecting piece 61 is substantially parallel to the second connecting piece 62. A first obtuse angle is defined between the third connecting piece 63 and the first connecting piece 61. A second obtuse angle is defined between the third connecting piece 63 and the second connecting piece 62. A latching piece 611 extends from a side edge of the first connecting piece 61. Two second pivoting pieces 621 extend from two opposite edges of the second connecting piece 62. Each second pivoting piece 621 defines a second pivoting hole 6211. In one embodiment, each second pivoting piece 621 is substantially perpendicular to the first connecting piece 61 and the second connecting piece 62.

The rotating member 70 comprises a pressing piece 71, a pair of third pivoting pieces 73, and a pair of fourth pivoting pieces 74. The pair of third pivoting pieces 73 and the pair of fourth pivoting pieces 74 extend reversely from two opposite edges of the pressing piece 71. The pressing piece 71 defines a receiving hole 711. Each third pivoting piece 73 defines a third pivoting hole 731. Each fourth pivoting piece 74 defines a fourth pivoting hole 741.

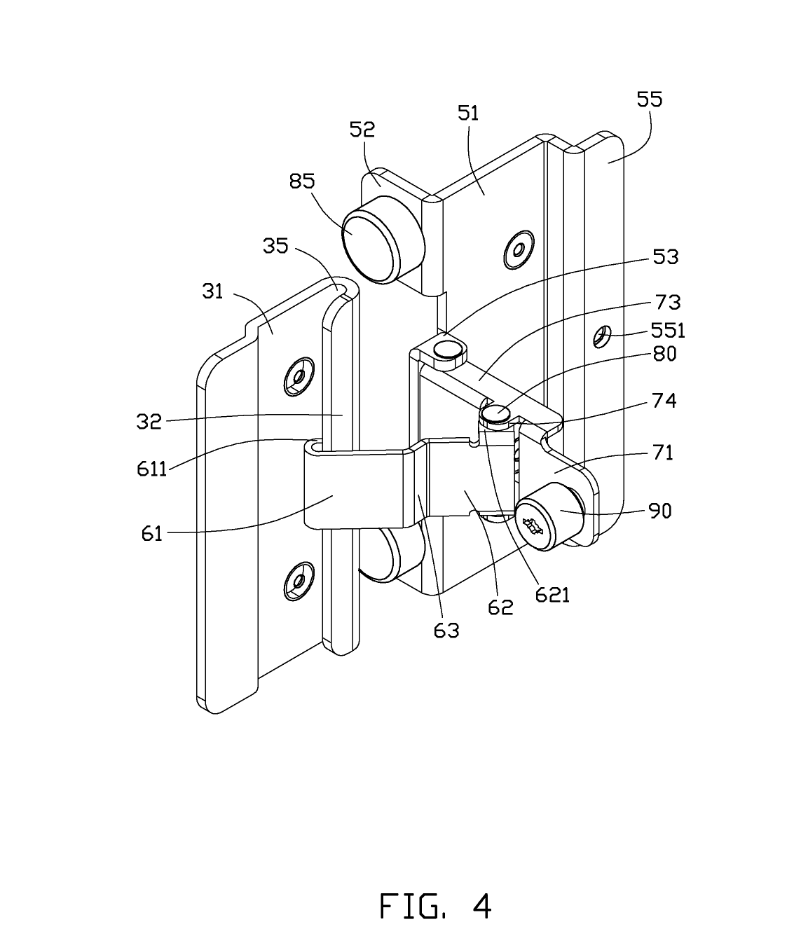

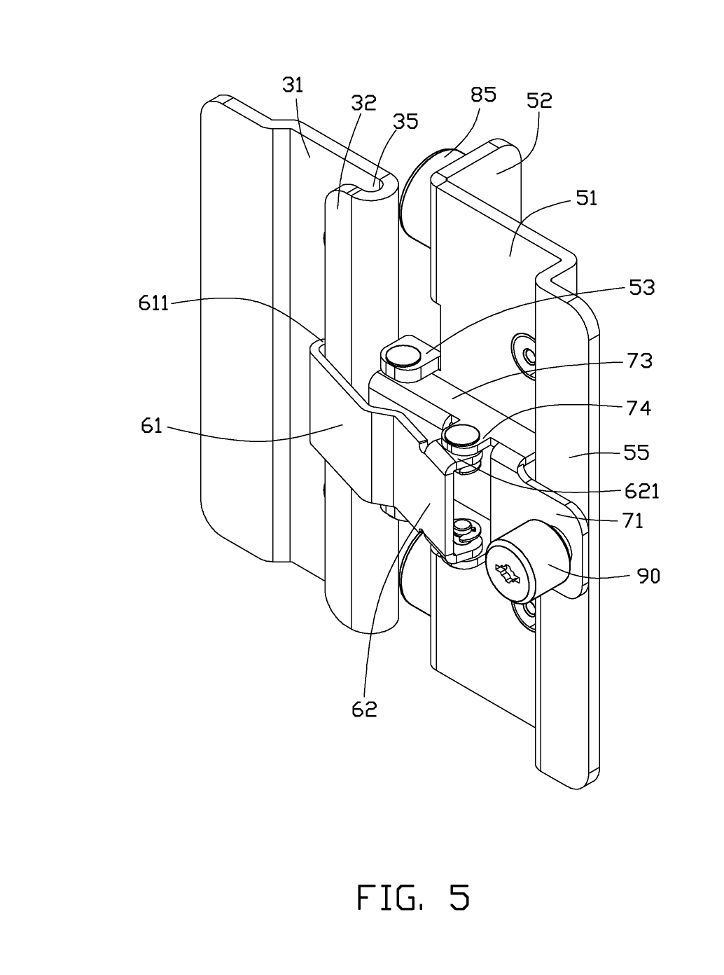

Referring to FIG. 4 and FIG. 5, the connecting assembly 100 further comprises a plurality of shafts 80, a plurality of washers 81, and a mounting member 90. In assembly of the connecting assembly 100, the rotating member 70 is placed between the two first pivoting pieces 53, the third pivoting piece 73 abuts the first pivoting piece 53, and the first pivoting hole 731 is aligned with the first pivoting hole 531. The rotating member 70 is pivotably mounted to the second installation member 50 by two of the plurality of shafts 80 and two of the plurality of washers 81. The connecting member 60 is placed between the two fourth pivoting pieces 74, each fourth pivoting piece 74 abuts each second pivoting piece 621, and the fourth pivoting hole 741 is aligned with the second pivoting hole 6211. The latching piece 611 is engaged in the latching slot 35. The first installation piece 31 is coplanar with the second installation piece 51. The connecting member 60 is pivotably mounted to the rotating member 70 by another two of the plurality of shafts 80 and another two of the plurality of washers 81. The connecting member 60 is rotatable relative to the first installation member 30 about the latching slot 35. The mounting member 90 comprises a mounting portion 91. The mounting member 90 is secured to the pressing piece 71. The mounting portion 91 extends out of the receiving hole 711. In one embodiment, a cross-section of the mounting portion 91 is circular, and the locking hole 551 is circular. A diameter of the mounting portion 91 is substantially equal to a diameter of the locking hole 551.

The connecting member 60 and the rotating member 70 are rotatable relative to the first installation member 30 and the second installation member 50 between a locked position and an unlocked position. When the connecting member 60 and the rotating member 70 are in the unlocked position, a first angle is defined between the first connecting piece 61 and the first installation piece 31, an acute angle is defined between the pressing piece 71 and the second installation piece 51, and the mounting portion 91 is disengaged from the locking hole 551. In this position, the latching piece 611 can be removed from the latching slot 35. When the connecting member 60 and the rotating member 70 are in the locked position, a second angle is defined between the first connecting piece 61 and the first installation piece 31, the pressing piece 71 is substantially parallel to the second installation piece 51 and abuts the locking piece 55, and the mounting portion 91 is engaged in the locking hole 551 to prevent the rotating member 70 from rotating. The first angle is greater than the second angle.

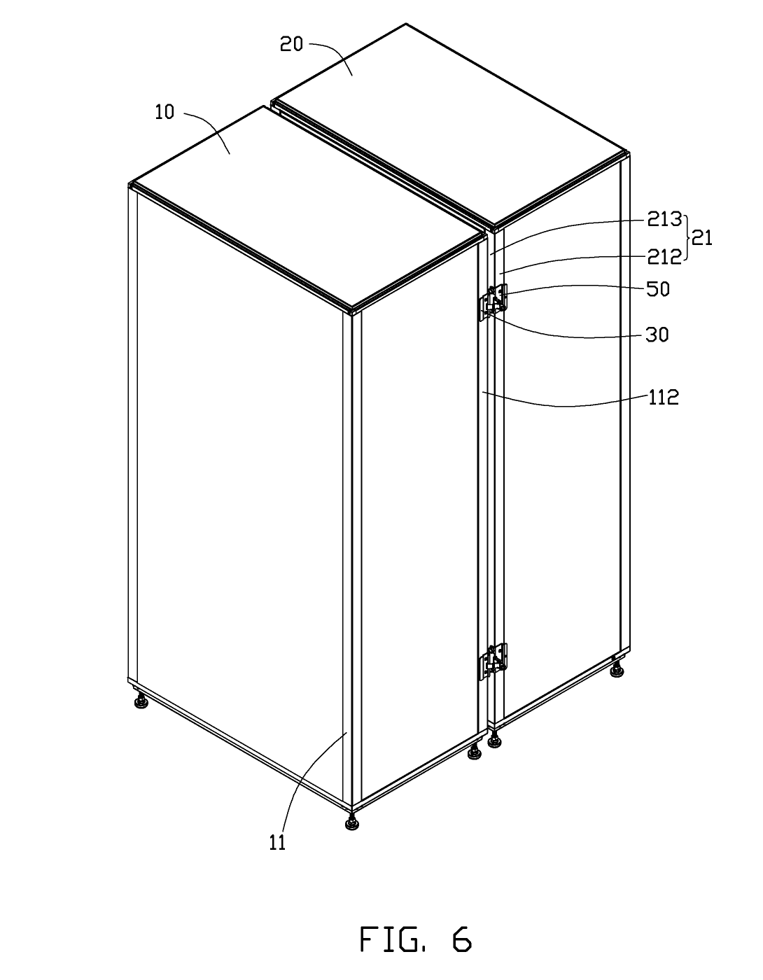

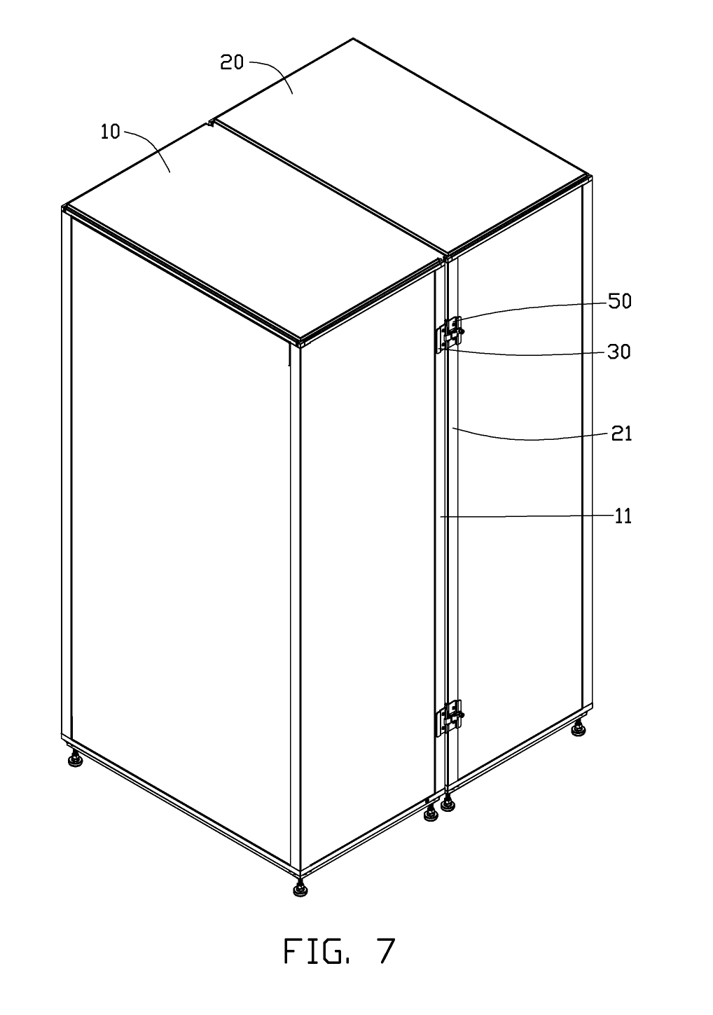

FIG. 6 and FIG. 7 show the connecting assembly 100 used for securing the first electronic device enclosure 10 to the second electronic device enclosure 20. In assembly of the first electronic device enclosure 10 and the second electronic device enclosure 20, the first installation post 311 is engaged in the first installation slot 1121 to secure the first installation member 30 to the first electronic device enclosure 10. The second installation post 511 is engaged in the second installation slot 2121. Two locking members 85, such as screws, are locked into the installation 521 and the mounting hole, to secure the second installation member 50 to the second electronic device enclosure 20. The rotating member 60 and the connecting member 70 are rotated in the unlocked position. The mounting member 90 is pressed towards the second installation member 50 to rotate the connecting member 60 towards the second installation member 50, until the connecting member 60 and the rotating member 70 are in the locked position. Thus, the connecting assembly 100 secures the first electronic device enclosure 10 to the second electronic device enclosure 20.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. An electronic device enclosure assembly comprising:
a first electronic device enclosure;
a second electronic device enclosure; and
a connecting assembly comprising a first installation member, a second installation member, a connecting member, a rotating member, and a mounting member secured to the rotating member;
wherein the first installation member is secured to the first electronic device enclosure; the second installation member is secured to the second electronic device enclosure; the connecting member is rotatably mounted to the first installation member and the rotating member; the rotating member is rotatably mounted to the second installation member; the second installation member defines a locking hole, and the mounting member is capable of engaging in the locking hole to prevent the rotating member from rotating relative to the second installation member; and the connecting member secures the first installation member to the second installation member.

2. The electronic device enclosure assembly of claim 1, wherein the first installation member comprises a first installation piece and a flange bent from the first installation piece; a latching slot is defined between the first installation piece and the flange; the connecting member comprises a latching piece, and the latching piece is engaged in the latching slot and rotatable about the flange.

3. The electronic device enclosure assembly of claim 2, wherein the connecting member comprises a first connecting piece, a second connecting piece, and a third connecting piece; the third connecting piece is connected between the first connecting piece and the second connecting piece; the latching piece extends from the first connecting piece; and the second connecting piece is rotatably mounted to the rotating member.

4. The electronic device enclosure assembly of claim 3, wherein the first connecting piece is substantially parallel to the second connecting piece; a first obtuse angle is defined between the third connecting piece and the first connecting piece; and a second obtuse angle is defined between the third connecting piece and the second connecting piece.

5. The electronic device enclosure assembly of claim 3, wherein the second installation member comprises a second installation piece, a first pivoting piece, and a locking piece; the first pivoting piece and the locking piece extend from two opposite edges of the second installation piece; a second pivoting piece extends from the second connecting piece; the rotating member comprises a pressing piece, and a third pivoting piece and a fourth pivoting piece extending from two opposite edges of the pressing piece; the first pivoting piece is pivotably mounted to the third pivoting piece; and the second pivoting piece is pivotably mounted to the fourth pivoting piece.

6. The electronic device enclosure assembly of claim 5, wherein the first pivoting piece is substantially perpendicular to the second installation piece, the second pivoting piece is substantially perpendicular to the second connecting piece, and the third pivoting and the fourth pivoting piece are substantially perpendicular to the pressing piece.

7. The electronic device enclosure assembly of claim 5, wherein the locking piece is substantially parallel to the second installation piece; the locking hole is defined in the locking piece; and the mounting member is secured to the pressing piece.

8. The electronic device enclosure assembly of claim 5, wherein the connecting member and the rotating member are rotatable between a locked position and an unlocked position; when the connecting member and the rotating member are in the locked position, a first angle is defined between the first connecting piece and the first installation piece, the pressing piece is substantially parallel to the second installation piece, the pressing piece abuts the locking piece, and the mounting member is engaged in the locking hole; when the connecting member and the rotating member are in the unlocked position, a second angle is defined between the first connecting piece and the first installation piece, an acute angle is defined between the pressing piece and the second installation piece, and the mounting member is disengaged from the locking hole.

9. The electronic device enclosure assembly of claim 8, wherein the first angle is greater than the second angle.

10. The electronic device enclosure assembly of claim 5, wherein the mounting member comprises a mounting portion, the pressing piece defines a receiving hole, and the mounting piece extends out of the receiving hole; a cross-section of the mounting portion is circular, the locking hole is circular, and a diameter of the mounting portion is substantially equal to a diameter of the locking hole.

11. An electronic device enclosure assembly comprising:
a first electronic device enclosure;
a second electronic device enclosure; and
a connecting assembly comprising a first installation member, a second installation member, a connecting member, a rotating member, and a mounting member secured to the rotating member;
wherein the first installation member is secured to the first electronic device enclosure; the second installation member is secured to the second electronic device enclosure; the connecting member is rotatably mounted to the first installation member and the rotating member; the rotating member is rotatably mounted to the second installation member; the second installation member defines a locking hole; the connecting member and the rotating member are rotatable between a locked position and an unlocked position; when the connecting member and the rotating member are in the locked position, the mounting member is engaged in the locking hole to secure the first installation member to the second installation member; when the connecting member and the rotating member are in the unlocked position, the mounting member is disengaged from the locking hole, and the first installation member is removable from the second installation member.

12. The electronic device enclosure assembly of claim 11, wherein the first installation member comprises a first installation piece and a flange bent from the first installation piece; a latching slot is defined between the first installation piece and the flange; the connecting member comprises a latching piece, and the latching piece is engaged in the latching slot and rotatable about the flange.

13. The electronic device enclosure assembly of claim 12, wherein the connecting member comprises a first connecting piece, a second connecting piece, and a third connecting piece; the third connecting piece is connected between the first connecting piece and the second connecting piece; the latching piece extends from the first connecting piece; and the second connecting piece is rotatably mounted to the rotating member.

14. The electronic device enclosure assembly of claim 13, wherein the first connecting piece is substantially parallel to the second connecting piece; a first obtuse angle is defined between the third connecting piece and the first connecting piece; and a second obtuse angle is defined between the third connecting piece and the second connecting piece.

15. The electronic device enclosure assembly of claim 13, wherein the second installation member comprises a second installation piece, a first pivoting piece, and a locking piece; the first pivoting piece and the locking piece extend from two opposite edges of the second installation piece; a second pivoting piece extends from the second connecting piece; the rotating member comprises a pressing piece, a third pivoting piece and a fourth pivoting piece extend from two opposite edges of the pressing piece; the first pivoting piece is pivotably mounted to the third pivoting piece; and the second pivoting piece is pivotably mounted to the fourth pivoting piece.

16. The electronic device enclosure assembly of claim 15, wherein the first pivoting piece is substantially perpendicular to the second installation piece, the second pivoting piece is substantially perpendicular to the second connecting piece, and the third pivoting and the fourth pivoting piece are substantially perpendicular to the pressing piece.

17. The electronic device enclosure assembly of claim 15, wherein the locking piece is substantially parallel to the second installation piece; the locking hole is defined in the locking piece; and the mounting member is secured to the pressing piece.

18. The electronic device enclosure assembly of claim 15, wherein when the connecting member and the rotating member are in the locked position, a first angle is defined between the first connecting piece and the first installation piece, the pressing piece is substantially parallel to the second installation piece, and the pressing piece abuts the locking piece; when the connecting member and the rotating member are in the unlocked position, a second angle is defined between the first connecting piece and the first installation piece, an acute angle is defined between the pressing piece and the second installation piece, and the latching piece is removable from the latching slot.

19. The electronic device enclosure assembly of claim 18, wherein the first angle is greater than the second angle.

20. The electronic device enclosure assembly of claim 15, wherein the mounting member comprises a mounting portion, the pressing piece defines a receiving hole, and the mounting piece extends out of the receiving hole; a cross-section of the mounting portion is circular, the locking hole is circular, and a diameter of the mounting portion is substantially equal to a diameter of the locking hole.
